(19) United States
(12) Patent Application Publication
(10) Pub. No.: US 2026/0206147 A1
(43) Pub. Date: Jul. 16, 2026

(54) METHOD FOR FORMING AN ADHESION BUFFER LAYER ON THE WALLS OF HIGH ASPECT RATIO THROUGH-HOLES OF AN INSULATING SUBSTRATE

(71) Applicant: Ming Chi University of Technology, New Taipei City (TW)

(72) Inventors: Chi-Lung CHANG, New Taipei City (TW); Fu-Sen YANG, New Taipei City (TW)

(21) Appl. No.: 19/423,277

(22) Filed: Dec. 17, 2025

(30) Foreign Application Priority Data
Jan. 15, 2025 (TW) 114101683

(51) Int. Cl. H05K 3/38; H05K 3/16

(52) U.S. Cl. CPC H05K 3/388; H05K 3/16; H05K 2203/0766; H05K 2203/085

(57) ABSTRACT

A method for forming an adhesion buffer layer on the walls of high aspect ratio through-holes of an insulating substrate, mainly comprises first preparing a high-power impulse magnetron sputtering system, and then arranging a plurality of metal targets in a sputtering chamber. Subsequently, an insulating substrate with a plurality of high aspect ratio through-holes is fixed in the sputtering chamber by a rotary fixture, wherein the aspect ratio of each high aspect ratio through-hole is greater than 4. Afterwards, the sputtering chamber is evacuated to form a vacuum-like environment in the sputtering chamber. Then, an argon gas is introduced into the sputtering chamber. Finally, an adhesion buffer layer is deposited on the inner walls of the high aspect ratio through-holes by a high-power impulse magnetron sputtering process for a subsequent hole-filling process to fill the high aspect ratio through-holes with a conductive metal.

This application claims the benefit of Taiwan Patent Application Serial No. 114101683, filed on Jan. 15, 2025, the subject matter of which is incorporated herein by reference.

### BACKGROUND OF THE INVENTION

### (1) Field of the Invention

The invention relates to a method for forming an adhesion buffer layer, and more particularly to a method for forming an adhesion buffer layer on the walls of high aspect ratio through-holes of an insulating substrate.

### (2) Description of the Prior Art

With the continuous development of technology, application areas such as artificial intelligence, the Internet of Things, and the Internet of Vehicles are gradually maturing and expanding. To meet the ever-increasing demand for improved chip performance, the semiconductor industry has been making unremitting efforts in chip miniaturization technology. In recent years, gate length has been further reduced from 7 nanometers to 3 nanometers or even 2 nanometers. While these technological breakthroughs have yielded remarkable results, they have also brought chip manufacturing technology closer to the physical limits of Moore's Law. Therefore, finding new technological approaches to improve chip performance has become a major challenge for the semiconductor industry.

With the advancement of technology, “heterogeneous integration” technology, which utilizes 3D structural design to stack and integrate chips with different functions, has emerged. This novel packaging method represents a fundamental change compared to traditional 2D planar packaging. By vertically stacking multiple chips, not only can the integration and performance of the chips be effectively improved, but a new possibility can also be provided for realizing smaller, lower power consumption and more efficient electronic products.

In “heterogeneous integration” technology, the interposer is a crucial structure, which requires metal wires as channels for vertical signal transmission. Therefore, when implementing the aforementioned vertical stacking structure, it is necessary to perform through-hole processing on the insulating substrate (such as glass substrate, ceramic substrate, etc.) to facilitate the subsequent filling of metal wires. With the continuous advancement of technology, the aspect ratio (AR) of through-holes has also been increasing (in practice, an aspect ratio greater than 4 is called a high aspect ratio), which places higher demands on the processing technology. After the through-hole machining is completed, the next step is to perform a hole-filling process to enable vertical signal transmission.

In traditional sputtering processes, the ion movement is usually perpendicular to the surface of the object to be coated, and this method is only very effective on planar structures. However, as the aspect ratio of through-holes gradually increases, traditional sputtering methods struggle to completely fill the inside of the through-holes (due to insufficient ion energy). Therefore, wet processes are often required for thin film deposition to ensure that the through-holes are adequately filled with metal.

However, wet processes also have some obvious drawbacks. First, because chemical solutions have a relatively short shelf life, this means that the solution needs to be replaced frequently, and additional treatment of the waste liquid is also required, resulting in relatively high costs (or pollution problems caused by the discharge of waste liquid). Secondly, compared to sputtering processes, wet processes also have the problem of relatively low adhesion between the thin film and the substrate, which can lead to peeling and short circuits in subsequent hole-filling processes due to defects, affecting the long-term reliability and performance of the finished wafers.

### SUMMARY OF THE INVENTION

Given that the sputtered ions in traditional sputtering processes have low energy and lack lateral movement capabilities, they cannot completely fill the high aspect ratio through-holes. In most circumstances, a wet process, which is more expensive and has poorer adhesion, is chosen for processing.

Therefore, the main purpose of the present invention is to provide a method for forming an adhesion buffer layer on the walls of high aspect ratio through-holes of an insulating substrate. The high-power impulse magnetron sputtering (HiPIMS) process is performed using a high-power impulse magnetron sputtering system to deposit an adhesion buffer layer on the inner walls of high aspect ratio through-holes of an insulating substrate, which is then used in subsequent hole-filling process to fill the high aspect ratio through-hole with a conductive metal.

Compared to traditional sputtering process, high-power impulse magnetron sputtering process has higher ion kinetic energy, enabling the deposition of high aspect ratio through-holes, and has better adhesion, making the thin film less prone to peeling off. In addition, compared to wet process, high-power impulse magnetron sputtering process is a dry process that does not require the use of chemical solutions or waste liquid treatment, thus offering advantages such as lower cost and no pollution.

Accordingly, the necessary technical means adopted by the present invention to solve the problems of prior arts is to provide a method for forming an adhesion buffer layer on the walls of high aspect ratio through-holes of an insulating substrate, comprising the following steps of:

First, a high-power impulse magnetron sputtering system is prepared, which has a sputtering chamber. Then, a plurality of metal targets are arranged in the sputtering chamber.

The next step is to fix an insulating substrate with a plurality of high aspect ratio through-holes in the sputtering chamber by a rotary fixture, wherein the aspect ratio of each high aspect ratio through-hole is greater than 4.

Next, the sputtering chamber is evacuated to reduce the pressure inside the sputtering chamber to below 5×10⁻⁵ torr, and then an argon gas is introduced into the sputtering chamber.

Finally, a high-power impulse magnetron sputtering process is performed to deposit an adhesion buffer layer on the inner walls of the high aspect ratio through-holes, which will be used for a subsequent hole-filling process to fill the high aspect ratio through-hole with a conductive metal.

Each of the aforementioned metal targets is composed of at least one of copper, titanium, chromium, zirconium, tungsten, aluminum, molybdenum, tantalum, yttrium, nickel, gold, silver and platinum, and in the high-power impulse magnetron sputtering process, the sputtering power of each of the aforementioned metal targets is between 0.5 kW and 5 kW.

Based on the aforementioned necessary technical means, the following auxiliary technical means can be derived. Preferably, the insulating substrate is made of glass or ceramic.

Based on the aforementioned necessary technical means, the following auxiliary technical means can be derived. Preferably, the step of fixing the insulating substrate by the rotary fixture further includes following steps of: first, preparing the insulating substrate, and then, removing the grease adhering to the insulating substrate. The next step is to clean the insulating substrate with pure water, and then, dry the insulating substrate. The final step is to place the insulating substrate in an oven to dry, and place the insulating substrate in the sputtering chamber within a valid time limit.

Based on the aforementioned necessary technical means, the following auxiliary technical means can be derived. Preferably, the step of using the high-power impulse magnetron sputtering process further includes following steps of: first, applying an electric field in the sputtering chamber to dissociate the argon gas into argon ions, and using the argon ions to bombard the insulating substrate. The next step is to use one of the metal ions generated by the metal targets to bombard the insulating substrate with ions. The final step is to perform the in high-power impulse magnetron sputtering process to deposit the adhesion buffer layer on the inner walls of the high aspect ratio through-holes for the subsequent hole-filling process.

Based on the aforementioned necessary technical means, the following auxiliary technical means can be derived. Preferably, the high-power impulse magnetron sputtering system further includes a conductive plate adjacent to the rotary fixture, the conductive plate being used to control the direction of movement of one of the metal ions by using a bias voltage.

Based on the aforementioned necessary technical means, the following auxiliary technical means can be derived. Preferably, in the high-power impulse magnetron sputtering process, the adhesion buffer layer is formed by depositing in the type of single-sided coating, double-sided coating, or rotational coating on the inner walls of the high aspect ratio through-holes.

To summarize, the method of the present invention for forming an adhesion buffer layer on the walls of high aspect ratio through-holes of an insulating substrate is to use a high-power impulse magnetron sputtering system to perform a high-power impulse magnetron sputtering process, thereby depositing and forming an adhesion buffer layer on the inner walls of the high aspect ratio through-holes of the insulating substrate, so as to allow for subsequent hole-filling process to fill the high aspect ratio through-holes with a conductive metal.

Compared to traditional sputtering process, high-power impulse magnetron sputtering processes has higher ion kinetic energy, enabling the deposition of high aspect ratio through-holes, and has better adhesion, making the thin film less prone to peeling off. In addition, compared to wet process, high-power impulse magnetron sputtering process is a dry process that does not require the use of chemical solutions or waste liquid treatment, thus offering advantages such as lower cost and no pollution.

The specific embodiments used in the present invention will be further explained through the following embodiments and drawings.

### BRIEF DESCRIPTION OF THE DRAWINGS

The present invention will now be specified with reference to its preferred embodiment illustrated in the drawings, in which:

FIG. 1 is a plan view of the high-power impulse magnetron sputtering system used in the method of the present invention for forming an adhesion buffer layer on the walls of high aspect ratio through-holes of an insulating substrate;

FIG. 2 shows a flowchart of the method for forming an adhesion buffer layer on the walls of high aspect ratio through-hole of an insulating substrate, as provided in the first embodiment of the present invention;

FIG. 3 shows a method for forming an adhesion buffer layer on the walls of high aspect ratio through-holes of an insulating substrate, as provided in the first embodiment of the present invention, including a flowchart of the detailed preparation steps of the insulating substrate;

FIG. 4 shows a perspective view of the method provided in the first embodiment of the present invention for forming an adhesion buffer layer on the walls of high aspect ratio through-holes of an insulating substrate, wherein a high-power impulse magnetron sputtering process is performed in the type of single-sided coating;

FIG. 5 shows a cross-sectional view of the method provided in the first embodiment of the present invention for forming an adhesion buffer layer on the walls of high aspect ratio through-holes of an insulating substrate, wherein the adhesion buffer layer is deposited on the inner wall of the high aspect ratio through-hole;

FIG. 6 shows a cross-sectional view of the method provided in the first embodiment of the present invention for forming an adhesion buffer layer on the walls of high aspect ratio through-holes of an insulating substrate, wherein a subsequent hole-filling process is performed to fill the high aspect ratio through-hole with a conductive metal;

FIG. 7 shows a perspective view of the method provided in the second embodiment of the present invention for forming an adhesion buffer layer on the walls of high aspect ratio through-holes of an insulating substrate, wherein a high-power impulse magnetron sputtering process is performed in the type of double-sided coating;

FIG. 8 shows a cross-sectional view of the method provided in the second embodiment of the present invention for forming an adhesion buffer layer on the walls of high aspect ratio through-holes of an insulating substrate, wherein the adhesion buffer layer is deposited on the inner wall of the high aspect ratio through-hole;

FIG. 9 shows a perspective view of the method provided in the third embodiment of the present invention for forming an adhesion buffer layer on the walls of high aspect ratio through-holes of an insulating substrate, wherein a high-power impulse magnetron sputtering process is performed in the type of rotational coating; and

FIG. 10 shows a cross-sectional view of the method provided in the third embodiment of the present invention for forming an adhesion buffer layer on the walls of high aspect ratio through-holes of an insulating substrate, wherein the adhesion buffer layer is deposited on the inner wall of the high aspect ratio through-hole.

### DESCRIPTION OF THE PREFERRED EMBODIMENT

The invention disclosed herein is directed to a method for forming an adhesion buffer layer on the walls of high aspect ratio through-holes of an insulating substrate. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

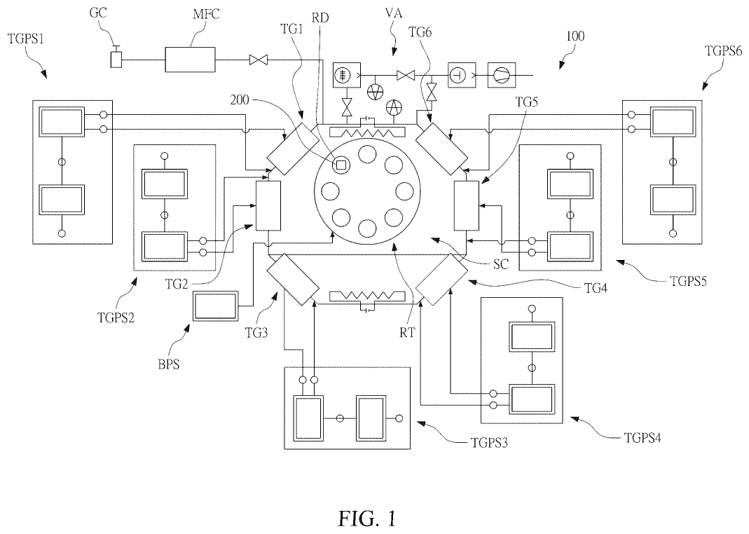

Referring to FIG. 1, FIG. 1 is a plan view of the high-power impulse magnetron sputtering system used in the method of the present invention for forming an adhesion buffer layer on the walls of high aspect ratio through-holes of an insulating substrate. As shown in FIG. 1, the method for forming an adhesion buffer layer on walls of high aspect ratio through-holes of an insulating substrate provided in the first embodiment of the present invention is applied to a high-power impulse magnetron sputtering system 100.

The high-power impulse magnetron sputtering system 100 has a sputtering chamber SC, and the sputtering chamber SC contains a revolving platform RT and a plurality of metal targets. In the present embodiment, a total of six metal targets TG1 to TG6 are included, and they are arranged around the revolving platform RT. Furthermore, the material of the metal targets described in this embodiment is composed of at least one of copper, titanium, chromium, zirconium, tungsten, aluminum, molybdenum, tantalum, yttrium, nickel, gold, silver and platinum.

As mentioned above, the metal targets TG1 to TG6 are respectively electrically connected to the high-power impulse magnetron power supply TGPS1 to TGPS6, and the high-power impulse magnetron power supply can be, for example, the power supply with type No. of Hüttinger 4002 G2 or Melec SPIK 3000A.

In addition, the high-power impulse magnetron sputtering system 100 is equipped with an argon gas supply source GC, a mass flow controller MFC, a vacuum pump assembly VA, and a bias voltage power supply BPS. The argon gas supply source GC is connected to the sputtering chamber SC through the mass flow controller MFC, and the flow rate of argon gas into the sputtering chamber SC is controlled by the mass flow controller MFC. The bias voltage power supply BPS can be, for example, the bias voltage power supply with type No. of Hüttinger 4020 G2, used to generate bias voltage.

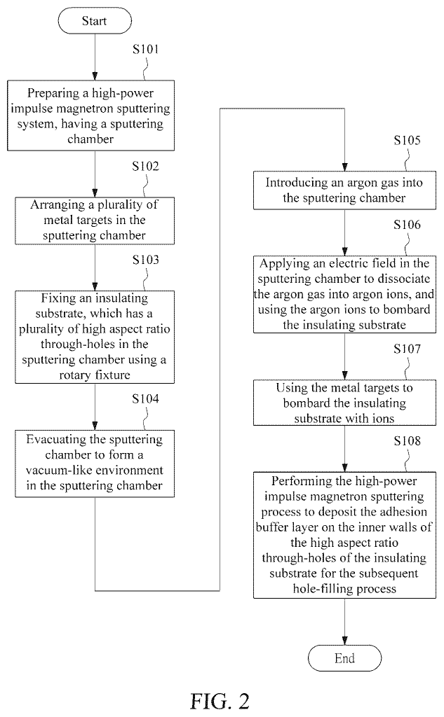

Referring to FIG. 2, FIG. 2 shows a flowchart of the method for forming an adhesion buffer layer on the walls of high aspect ratio through-hole of an insulating substrate, as provided in the first embodiment of the present invention. As shown in FIG. 1 and FIG. 2, a method for forming an adhesion buffer layer ABL on the walls of high aspect ratio through-holes TH of an insulating substrate 200 includes the following steps of S101 to S108.

Step S101 involves preparing a high-power impulse magnetron sputtering system 100, having a sputtering chamber SC.

Step S102 involves arranging a plurality of metal targets TG1 to TG6 in the sputtering chamber SC respectively.

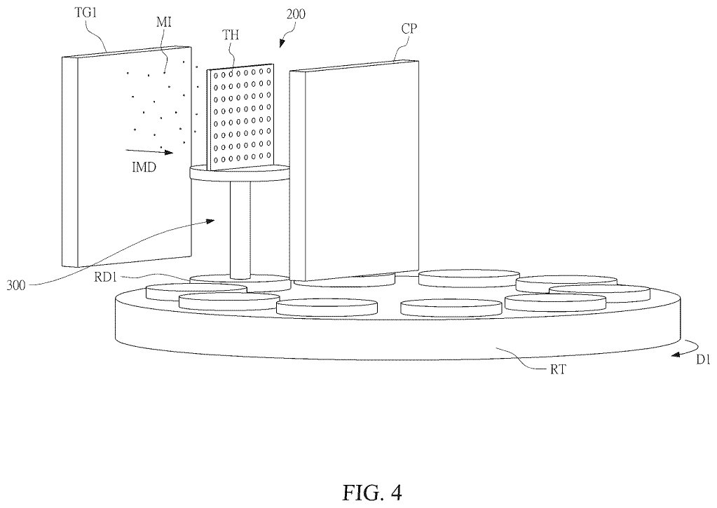

Step S103 involves fixing an insulating substrate 200, which has a plurality of high aspect ratio through-holes (only one high aspect ratio through-hole TH is shown), in the sputtering chamber SC using a rotary fixture 300 (shown in FIG. 4).

In the present embodiment, the insulating substrate 200 is made of glass or ceramic, and the aspect ratio AR of one of the high aspect ratio through-holes TH is greater than 4 (in practice, the aspect ratio can reach 10, but is not limited to this). As mentioned above, the rotary fixture 300 is fixed to the rotating disk RD1 to drive the insulating substrate 200 to rotate as the rotating disk RD1 rotates. In practice, the rotary fixture 300 can fix the insulating substrate 200 by clamping, but is not limited to this. The structure and working principle of the rotary fixture 300 are prior art and will not be described again in the present embodiment.

Step S104 involves evacuating the sputtering chamber SC to form a vacuum-like environment in the sputtering chamber SC. The vacuum-like environment refers to an environment with extremely low air pressure that is close to a vacuum. In the present embodiment, the vacuum pump assembly VA used in the high-power impulse magnetron sputtering system 100 includes a mechanical pump, a Roots pump, and a turbomolecular pump. Mechanical pump can reduce the pressure in the sputtering chamber SC to a low vacuum pressure of 5×10⁻² torr; Roots pump can further reduce the pressure in the sputtering chamber SC to a medium vacuum pressure of 5×10⁻⁴ torr; turbomolecular pump can further reduce the pressure in the sputtering chamber SC to a high vacuum pressure of 5×10⁻⁵ torr (for better vacuum effect, preferably, turbomolecular pump is used to further reduce the pressure to 1×10⁻⁶ torr).

Step S105 involves introducing an argon gas into the sputtering chamber SC.

Step S106 involves applying an electric field in the sputtering chamber SC to dissociate the argon gas into argon ions, and using the argon ions to bombard the insulating substrate 200. The purpose of bombarding the insulating substrate 200 with argon ions is to remove fine dust adhering to the insulating substrate 200.

Step S107 involves using the metal targets TG1 to TG6 to bombard the insulating substrate 200 with ions. The purpose of using metal targets TG1 to TG6 to bombard the insulating substrate 200 with ions is to clean the surface of the insulating substrate 200 and increase its adhesion.

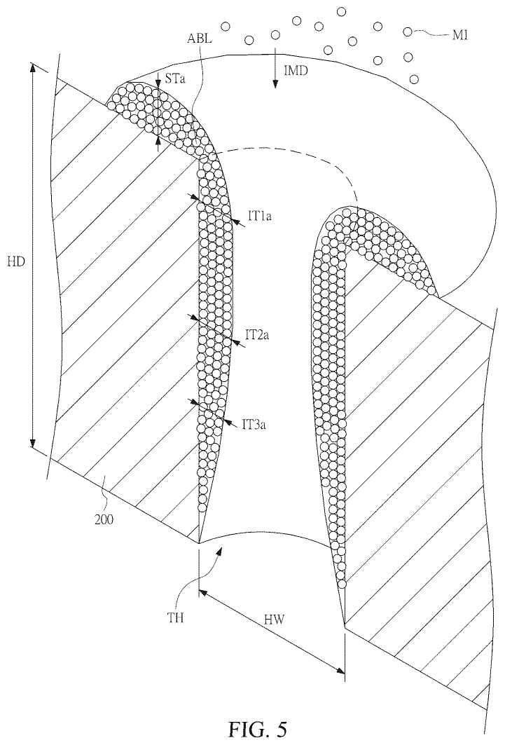

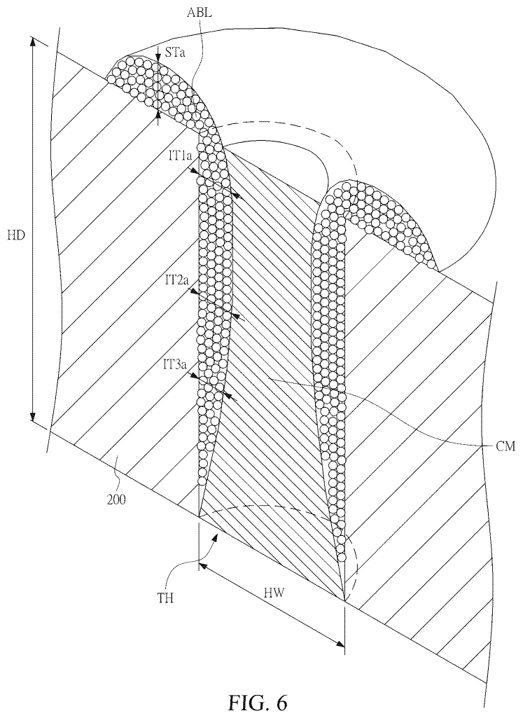

Step S108 involves performing the high-power impulse magnetron sputtering process to deposit the adhesion buffer layer ABL (shown in FIG. 5, often referred to as a seed layer) on the inner walls of the high aspect ratio through-holes TH of the insulating substrate 200 for the subsequent hole-filling process to fill the high aspect ratio through-holes TH with a conductive metal CM (e.g., copper, shown in FIG. 6). In the high-power impulse magnetron sputtering process, the power of the metal targets TG1 to TG6 is between 0.5 kW and 5 kW.

As mentioned above, in the present embodiment, the detailed process parameters of the high-power impulse magnetron sputtering process are shown in Table 1 below.

TABLE 1
High-power impulse magnetron sputtering process
parameters of the first embodiment.

| | |
|---|---|
| Deposition distance (mm) | 90-200 |
| Working pressure (torr) | 1 × 10⁻³-5 × 10⁻³ |
| Introduced gas (sccm) | Ar (60-250) |
| Deposition temperature (° C.) | between room temperature and 250 |
| Target power (kW) | 0.5-5 |
| Frequency (Hz) | 100-1000 |
| Duty cycle (%) | 1-10 |
| Bias voltage (V) | 0-(−120) |
| Deposition time (min) | 5-60 |
| Mode | monopolar/bipolar |

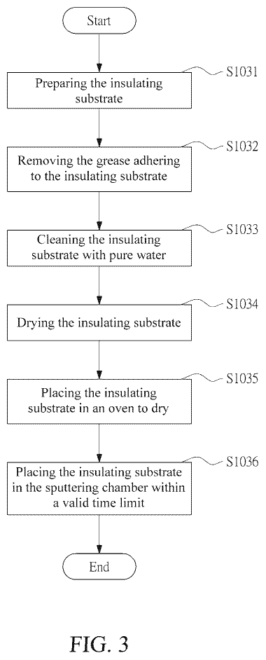

Referring to FIG. 3, FIG. 3 shows a method for forming an adhesion buffer layer on the walls of high aspect ratio through-holes of an insulating substrate, as provided in the first embodiment of the present invention, including a flowchart of the detailed preparation steps of the insulating substrate. As shown in FIG. 2 and FIG. 3, the step S103 further includes the following steps of S1031 to S1036.

Step S1031 involves preparing the insulating substrate 200. Step S1032 involves removing the grease adhering to the insulating substrate 200. Step S1033 involves cleaning the insulating substrate 200 with pure water. Step S1034 involves drying the insulating substrate 200. Step S1035 involves placing the insulating substrate 200 in an oven to dry. Step S1036 involves placing the insulating substrate 200 in the sputtering chamber SC within a valid time limit.

As mentioned above, step S1034 involves drying the insulating substrate 200 by, for example, using an air gun to spray air. Step S1035, for example, involves placing the dried insulating substrate 200 into an oven preheated to 70° C. and drying it in the oven for 10 minutes to ensure that no moisture remains. The valid time limit for step S1036 is, for example, one hour, mainly to prevent the dried insulating substrate 200 from being contaminated by being left in an open environment for too long.

Referring to FIG. 4, FIG. 4 shows a perspective view of the method provided in the first embodiment of the present invention for forming an adhesion buffer layer on the walls of high aspect ratio through-holes of an insulating substrate, wherein a high-power impulse magnetron sputtering process is performed in the type of single-sided coating.

As shown in FIG. 4, the high-power impulse magnetron sputtering system 100 is also provided with a conductive plate CP adjacent to the rotary fixtures 300 (in practice, the conductive plate CP is fixed to the rotary platform RT and rotates with the rotary platform RT, but is not limited thereto), and both the conductive plate CP and the rotary fixture 300 are electrically connected to the bias voltage power supply BPS.

When performing the high-power impulse magnetron sputtering process, different coating methods can be distinguished into single-sided coating type, double-sided coating type, and rotational coating type. The present embodiment will be described using single-sided coating; double-sided coating and rotational coating will be described in subsequent embodiments.

During the single-sided coating, the revolving platform RT rotates continuously along a revolution direction D1, while the rotating disk RD1 remains stationary. In other words, the insulating substrate 200 rotates along with the revolving platform RT, and always maintains a single-sided (same-sided) orientation facing the metal targets TG1 to TG6. As mentioned above, during the process, the metal target (taking metal target TG1 as an example) periodically sputters multiple metal ions (only one metal ion MI is indicated), and under the action of the electric field, they are accelerated to fly towards the insulating substrate 200 (compared to the wet process, when performing the high-power impulse magnetron sputtering process, the metal ion MI has higher energy and can be embedded in the inner wall with better adhesion).

In order to make the metal ions MI fly as far as possible towards the high aspect ratio through-hole TH of the insulating substrate 200, the bias voltage power supply BPS generates a bias voltage at the conductive plate CP to control the ion movement direction IMD of the metal ions MI. In addition, when the metal ions MI begin to deposit in high aspect ratio through-holes TH, the electricity generated by the bias voltage power supply BPS can be transmitted to the adhesion buffer layer ABL via the rotary fixture 300, thereby generating a bias voltage at the insulating substrate 200 to control the ion movement direction IMD of the metal ions MI.

Referring to FIG. 5, FIG. 5 shows a cross-sectional view of the method provided in the first embodiment of the present invention for forming an adhesion buffer layer on the walls of high aspect ratio through-holes of an insulating substrate, wherein the adhesion buffer layer is deposited on the inner wall of the high aspect ratio through-hole. As shown in FIG. 5, after the high-power impulse magnetron sputtering process in the type of single-sided coating, an adhesion buffer layer ABL is deposited and formed on the inner wall of the high aspect ratio through-hole TH (the outline of the through-hole TH is shown in dashed lines). The high aspect ratio through-hole TH has a through-hole depth HD and a through-hole width HW. In the present embodiment, the through-hole depth HD and the through-hole width HW are 450 μm and 100 μm, respectively, which means the aspect ratio is 4.5.

As mentioned above, the adhesion buffer layer ABL has a surface thickness STa, a first inner wall thickness IT1a, a second inner wall thickness IT2a and a third inner wall thickness IT3a. In the present embodiment, the surface thickness STa, the first inner wall thickness IT1a, the second inner wall thickness IT2a, and the third inner wall thickness IT3a are 590 nm, 275 nm, 45 nm, and 25 nm, respectively.

Referring to FIG. 6, FIG. 6 shows a cross-sectional view of the method provided in the first embodiment of the present invention for forming an adhesion buffer layer on the walls of high aspect ratio through-holes of an insulating substrate, wherein a subsequent hole-filling process is performed to fill the high aspect ratio through-hole with a conductive metal. As shown in FIG. 6, after the adhesion buffer layer ABL is deposited and formed on the inner wall of the high aspect ratio through-hole TH, subsequent hole-filling process can be performed to fill the high aspect ratio through-hole with the conductive metal CM to complete the preparation of the interposer.

Compared to direct adhesion to the insulating substrate 200, the conductive metal CM has better adhesion to the adhesion buffer layer ABL. Therefore, by first depositing the adhesion buffer layer ABL on the inner wall of the high aspect ratio through-hole TH, the subsequent hole-filling process (such as wet process or dry process) can be more favorable.

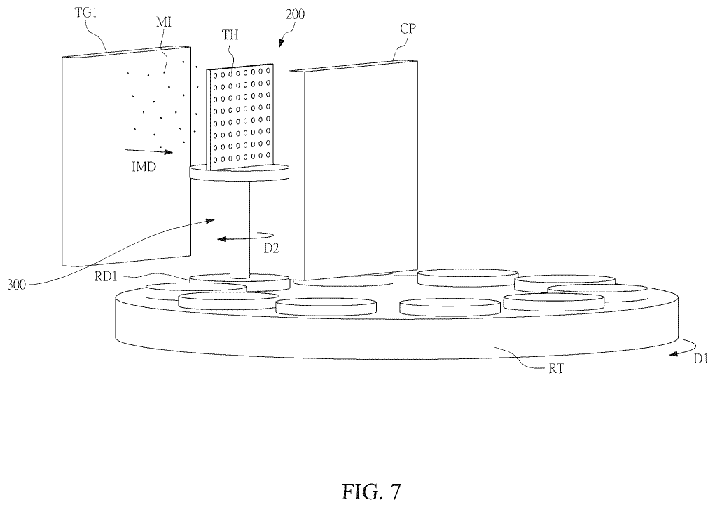

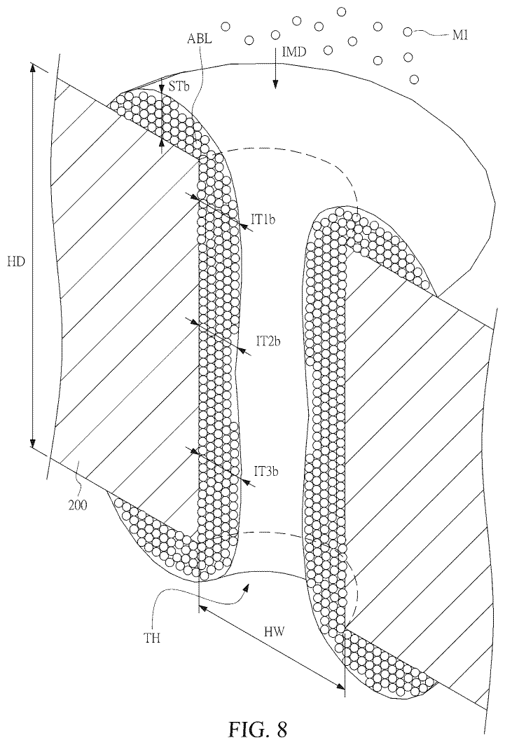

Referring to FIG. 7 and FIG. 8, FIG. 7 shows a perspective view of the method provided in the second embodiment of the present invention for forming an adhesion buffer layer on the walls of high aspect ratio through-holes of an insulating substrate, wherein a high-power impulse magnetron sputtering process is performed in the type of double-sided coating; and FIG. 8 shows a cross-sectional view of the method provided in the second embodiment of the present invention for forming an adhesion buffer layer on the walls of high aspect ratio through-holes of an insulating substrate, wherein the adhesion buffer layer is deposited on the inner wall of the high aspect ratio through-hole. Please refer to FIG. 1 and FIG. 6 together.

The high-power impulse magnetron sputtering system 100, steps S101 to S108, and steps S1031 to S1036 in the second embodiment are the same as or similar to those in the first embodiment. Please refer to the description in the corresponding paragraphs. They will not be repeated in this embodiment. The difference between the second embodiment and the first embodiment is that the second embodiment uses a high-power impulse magnetron sputtering process in the type of double-sided coating.

The first half of the process for double-sided coating is the same as that for single-sided coating. The revolving platform RT rotates continuously along the revolution direction D1, while the rotating disk RD1 remains stationary. After the first half of the process is completed (for example, when half of the deposition time has been reached), the revolving platform RT stops rotating. At the beginning of the second half of the process for double-sided coating, the rotating disk RD1 will first rotate 180 degrees along a rotation direction D2, that is, the other side of the insulating substrate 200 will face the metal targets TG1 to TG6, and then the revolving platform RT will continue to rotate along the revolution direction D1 to complete the second half of the process. In other words, the double-sided coating consists of two single-sided coatings, with the sides being switched during the process, so as to uniformly coat both sides of the insulating substrate 200.

After the high-power impulse magnetron sputtering process in the type of double-sided coating, an adhesion buffer layer ABL is deposited and formed on the inner wall of the high aspect ratio through-hole TH, and has a surface thickness STb, a first inner wall thickness IT1b, a second inner wall thickness IT2b and a third inner wall thickness IT3b. In the present embodiment, the surface thickness STb, the first inner wall thickness IT1b, the second inner wall thickness IT2b, and the third inner wall thickness IT3b are 715 nm, 250 nm, 85 nm, and 210 nm, respectively.

It is obvious that the double-sided coating has the adhesion buffer layer ABL deposited on both sides, while the single-sided coating only has the adhesion buffer layer ABL deposited on the surface adjacent to the metal targets TG1 to TG6. Additionally, after the double-sided coating, the adhesion buffer layer ABL not only has a larger average inner wall thickness, but is also more uniform, which is more favorable to the subsequent hole-filling process.

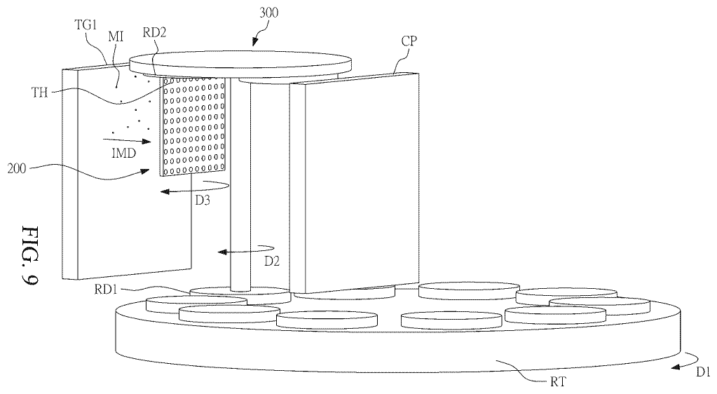

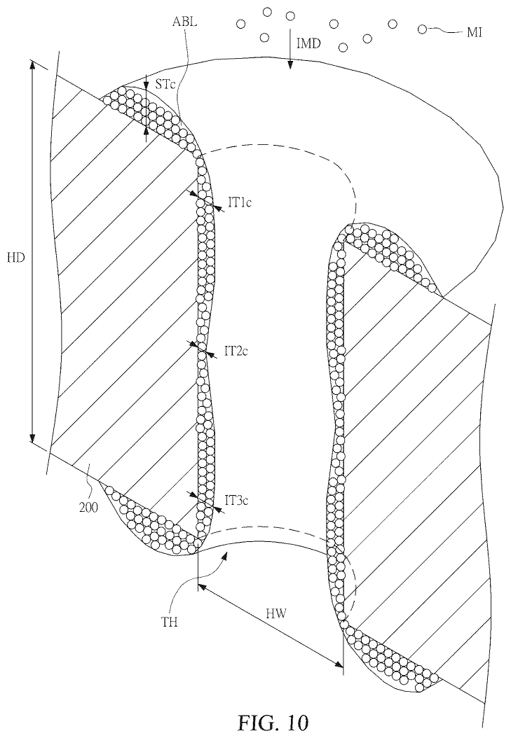

Referring to FIG. 9 and FIG. 10, FIG. 9 shows a perspective view of the method provided in the third embodiment of the present invention for forming an adhesion buffer layer on the walls of high aspect ratio through-holes of an insulating substrate, wherein a high-power impulse magnetron sputtering process is performed in the type of rotational coating; and FIG. 10 shows a cross-sectional view of the method provided in the third embodiment of the present invention for forming an adhesion buffer layer on the walls of high aspect ratio through-holes of an insulating substrate, wherein the adhesion buffer layer is deposited on the inner wall of the high aspect ratio through-hole. Please refer to FIG. 1 and FIG. 6 together.

The steps S101 to S108, and steps S1031 to S1036 in the third embodiment are the same as or similar to those in the first embodiment. Please refer to the description in the corresponding paragraphs. They will not be repeated in this embodiment. The difference between the third embodiment and the first embodiment is that the third embodiment uses a rotational coating method to perform a high-power impulse magnetron sputtering process. The rotary fixture 300 is provided with at least one rotating disk (only one rotating disk RD2 is indicated), and the rotating disk RD2 is provided with a structure that can fix the insulating substrate 200.

During the process of the rotational coating, the revolving platform RT continuously rotates along a revolution direction D1, while the rotating disks RD1 and RD2 continuously rotate along rotation directions D2 and D3, respectively. In other words, during the process, the insulating substrate 200 will continuously rotate to increase its step coverage.

After the high-power impulse magnetron sputtering process in the type of rotational coating, an adhesion buffer layer ABL is deposited and formed on the inner wall of the high aspect ratio through-hole TH, and has a surface thickness STc, a first inner wall thickness IT1c, a second inner wall thickness IT2c and a third inner wall thickness IT3c. In the present embodiment, the surface thickness STc, the first inner wall thickness IT1c, the second inner wall thickness IT2c, and the third inner wall thickness IT3c are 450 nm, 210 nm, 45 nm, and 180 nm, respectively.

It is obvious that the rotational coating has the adhesion buffer layer ABL deposited on both sides, while the single-sided coating only has the adhesion buffer layer ABL deposited on the surface adjacent to the metal targets TG1 to TG6. Additionally, after the rotational coating, the average inner wall thickness of the adhesion buffer layer ABL is slightly less than that of the double-sided coating, but its uniformity is still better than that of the single-sided coating, which is also beneficial to the subsequent hole-filling process.

Practically speaking, all three coating methods (single-sided coating, double-sided coating, and rotational coating) can be used to deposit the adhesion buffer layer ABL. In other words, current can be vertically conducted from one surface of the insulating substrate 200 to the other surface through the adhesion buffer layer ABL.

To summarize, the method of the present invention for forming an adhesion buffer layer on the walls of high aspect ratio through-holes of an insulating substrate is to use a high-power impulse magnetron sputtering system 100 to perform a high-power impulse magnetron sputtering process, thereby depositing and forming an adhesion buffer layer ABL on the inner walls of the high aspect ratio through-holes TH of the insulating substrate 200, so as to allow for subsequent hole-filling process to fill the high aspect ratio through-holes TH with a conductive metal CM.

Compared to traditional sputtering process, high-power impulse magnetron sputtering processes has higher ion kinetic energy, enabling the deposition of high aspect ratio through-holes, and has better adhesion, making the thin film less prone to peeling off. In addition, compared to wet process, high-power impulse magnetron sputtering process is a dry process that does not require the use of chemical solutions or waste liquid treatment, thus offering advantages such as lower cost and no pollution.

While the present invention has been particularly shown and described with reference to a preferred embodiment, it will be understood by those skilled in the art that various changes in form and detail may be without departing from the spirit and scope of the present invention.

What is claimed is:

1. A method for forming an adhesion buffer layer on the walls of high aspect ratio through-holes of an insulating substrate, comprising the steps of:
(a) preparing a high-power impulse magnetron sputtering system, having a sputtering chamber;
(b) arranging a plurality of metal targets in the sputtering chamber;
(c) fixing the insulating substrate with a plurality of high aspect ratio through-holes in the sputtering chamber by a rotary fixture, wherein the aspect ratio of each of the high aspect ratio through-holes is greater than 4;
(d) evacuating the sputtering chamber to reduce the pressure inside the sputtering chamber to below 5×10⁻⁵ torr;
(e) introducing an argon gas into the sputtering chamber; and
(f) depositing the adhesion buffer layer on the inner walls of the high aspect ratio through-holes by a high-power impulse magnetron sputtering process for a subsequent hole-filling process to fill the high aspect ratio through-holes with a conductive metal, wherein each of the metal targets is composed of at least one of copper, titanium, chromium, zirconium, tungsten, aluminum, molybdenum, tantalum, yttrium, nickel, gold, silver and platinum, and in the high-power impulse magnetron sputtering process, the sputtering power of each of the metal targets is between 0.5 kW and 5 kW.

2. The method of claim 1, wherein the insulating substrate is made of glass or ceramic.

3. The method of claim 1, wherein the step (c) further includes following steps:
(c1) preparing the insulating substrate;
(c2) removing the grease adhering to the insulating substrate;
(c3) cleaning the insulating substrate with pure water;
(c4) drying the insulating substrate;
(c5) placing the insulating substrate in an oven to dry; and
(c6) placing the insulating substrate in the sputtering chamber within a valid time limit.

4. The method of claim 1, wherein the step (f) further includes following steps:
(f1) applying an electric field in the sputtering chamber to dissociate the argon gas into argon ions, and using the argon ions to bombard the insulating substrate;
(f2) using one of the metal ions generated by the metal targets to bombard the insulating substrate with ions; and
(f3) performing the high-power impulse magnetron sputtering process to deposit the adhesion buffer layer on the inner walls of the high aspect ratio through-holes for the subsequent hole-filling process.

5. The method of claim 4, wherein the high-power impulse magnetron sputtering system further includes a conductive plate adjacent to the rotary fixture, the conductive plate being used to control the direction of movement of one of the metal ions by using a bias voltage.

6. The method of claim 1, wherein, in the high-power impulse magnetron sputtering process, the adhesion buffer layer is formed by depositing in the type of single-sided coating, double-sided coating, or rotational coating on the inner walls of the high aspect ratio through-holes.
